(19) United States
(12) Patent Application Publication
(10) Pub. No.: US 2017/0262335 A1
(43) Pub. Date: Sep. 14, 2017

(54) MEMORY DIAGNOSIS CIRCUIT

(71) Applicant: DENSO CORPORATION, Kariya-city, Aichi-pref. (JP)

(72) Inventors: Kazushi MATSUO, Kariya-city (JP); Hitoshi KUROYANAGI, Kariya-city (JP)

(21) Appl. No.: 15/510,264

(22) PCT Filed: Sep. 14, 2015
(86) PCT No.: PCT/JP2015/004656

§ 371 Date: Mar. 10, 2017

(30) Foreign Application Priority Data
Sep. 16, 2014 (JP) 2014-187659
May 14, 2015 (JP) 2015-099035

(51) Int. Cl. G06F 11/10; G11C 29/52

(52) U.S. Cl. CPC G06F 11/1068; G11C 29/52

(57) ABSTRACT

A memory diagnosis circuit includes: an error check and correction circuit carrying out an error check of data written into the memory and read out from the memory, having N (as a natural number to be 2 or more) or more bits in error, and an error correction of the data having (N−1) or less bits in error; a first data buffer storing data read out from the memory and corrected by the error check and correction circuit; a second data buffer directly storing data read out by the memory; a comparator comparing data values respectively in the first and second data buffers; and an error check and correction monitoring circuit. The error check and correction monitoring circuit validates the data value in the first data buffer based on a comparison result of the comparator; or invalidates the data value in the first data buffer and outputs an abnormal signal.

### CROSS REFERENCE TO RELATED APPLICATION

This application is based on Japanese Patent Application No. 2014-187659 filed on Sep. 16, 2014 and Japanese Patent Application No. 2015-99035 filed on May 14, 2015, the disclosures of which are incorporated herein by reference.

### TECHNICAL FIELD

The present disclosure relates to a memory diagnosis circuit that includes an error check and correction circuit for carrying out an error check and correction process on the data has been written into a memory and read out from the memory.

### BACKGROUND ART

When a memory such as a DRAM is used, an error check and correction circuit (ECC: Error Check and Correct) is arranged. The error check and correction circuit includes a function for detecting an error and correcting the error of data read out from the memory. However, when an error occurs in the error check and correction circuit itself, a countermeasure is necessary. For example, Patent Literature 1 discloses a microcomputer in which a memory and an error check and correction circuit are configured to be duplicated to compare the detection results of two error check and detection circuits for improving the reliability by selecting data at one of the two memories.

However, the configuration of duplex is cumbersome and leads to an increase in cost as the size of a system is made to be larger as disclosed in Patent Literature 1.

### PRIOR ART LITERATURES

### Patent Literature

Patent Literature 1: JP 2004-5627 A

### SUMMARY OF INVENTION

It is an object of the present disclosure to provide a memory diagnosis circuit for detecting an error occurred in an error check and correction circuit, which is configured to be a simple structure.

According to an aspect of the present disclosure, a memory diagnosis circuit includes: an error check and correction circuit that carries out an error check of data, which is written into a memory and read out from the memory, having N or more bits being in error, and an error correction of the data, which is written into a memory and read out from the memory, having (N−1) or less bits being in error; a first data buffer that stores data, which is read out from the memory and corrected by the error check and correction circuit; a second data buffer that directly stores data read out by the memory; a comparator that compares a value of the data stored in the first data buffer and a value of the data stored in the second data buffer; and an error check and correction monitoring circuit. In addition, the error check and correction monitoring circuit validates the value of the data stored in the first data buffer, when a comparison result of the comparator indicates (N−1) or less bits being in different between the value of the data stored in the first data buffer and the value of the data stored in the second data buffer, and the error check and correction monitoring circuit confirms that the error check and correction circuit carries out the error correction. Moreover, the error check and correction monitoring circuit invalidates the value of the data stored in the first data buffer and outputs an abnormal signal, when i) the comparison result of the comparator indicates (N−1) or less bits being different between the value of the data stored in the first data buffer and the value of the data stored in the second data buffer, and the error check and correction monitoring circuit confirms that the ECC does not carry out the error correction, or ii) the error check and correction monitoring circuit confirms that the error check and correction circuit carries out the error correction, although (N−1) or less bits not being in different between the value of the data stored in the first data buffer and the value of the data stored in the second data buffer, or iii) the comparison result of the comparator indicates N or more bits being in different between the value of the data stored in the first data buffer and the value of the data stored in the second data buffer, or iv) the error check and correction circuit confirms that the error check and correction circuit carries out the error check. Furthermore, N is a natural number to be equal to 2 or more.

Accordingly, when the comparator compares the data values stored in two data buffers respectively, the occurrence of abnormity in the error check and correction circuit is easily determined.

### BRIEF DESCRIPTION OF DRAWINGS

The above and other objects, features and advantages of the present disclosure will become more apparent from the following detailed description made with reference to the accompanying drawings. In the drawings:

FIG. 1 is a functional block diagram that illustrates the configuration of a memory diagnosis circuit according to a first embodiment of the present disclosure;

FIG. 2 is a functional block diagram that illustrates the configuration of a memory diagnosis circuit, and is a drawing that illustrates a state of each signal when a CPU reads out second check data according to a second embodiment of the present disclosure;

FIG. 3 is a drawing that illustrates a state of each signal when the CPU reads out first check data; and

FIG. 4 is a drawing that illustrates a state of each signal when the CPU reads out the first check data, which has an error in ECC bits.

### EMBODIMENTS FOR CARRYING OUT INVENTION

### First Embodiment

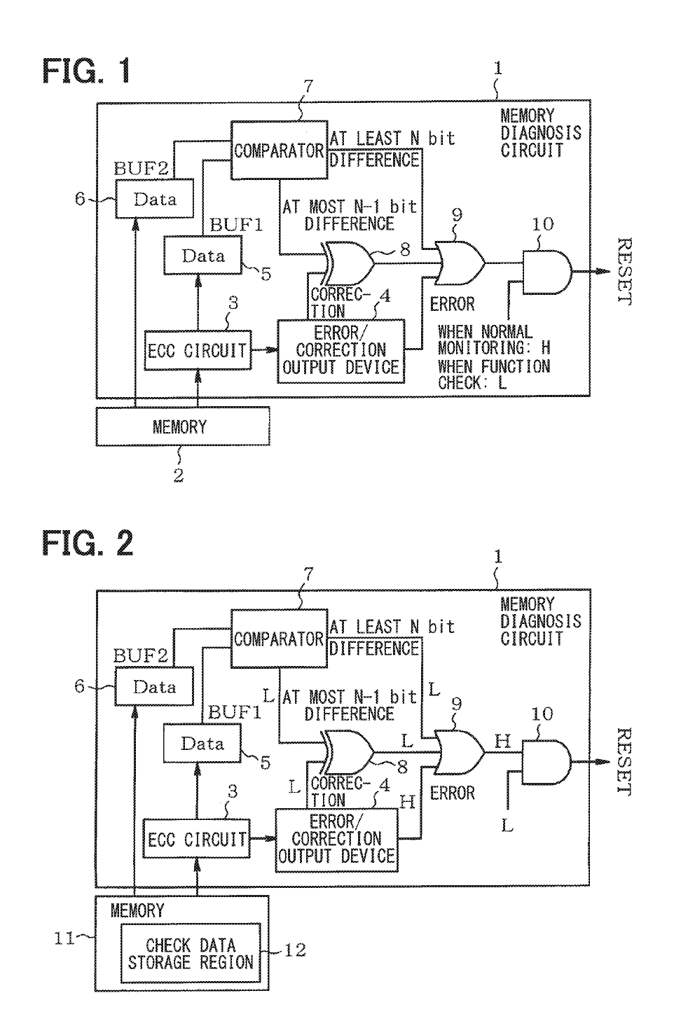

As illustrated in FIG. 1, a memory diagnosis circuit 1 in the present embodiment is arranged between a memory 2 and a CPU (not shown). The memory 2 may be, for example, a DRAM, an SRAM, an EEPROM, and a flash ROM. The memory diagnosis circuit 1 includes an ECC circuit 3 as an error check and correction circuit. When the CPU carries out a write-in process on the memory 2, the ECC circuit 3 generates a plurality of ECC bits as data for checking an error based on the write-in data, and then writes the check data and write-in data to the memory 2. In addition, when the CPU carries out a read-access process on the memory 2, the ECC circuit 3 reads out data and ECC bits from the memory 2 and performs a predetermined logical computation of the read-out data and ECC bits so as to check data having at least N bits (N>=2) being in error; and to correct data having at most (N−1) bits being in error. The following uses N=2 as an example for describing the present embodiment.

An error/correction output device 4 outputs a signal to indicate whether to perform correction of data having 1 bit being in error or to perform checking of data having at least 2 bits being in error based on the value of the read-out ECC bits when the CPU carries out the read-access process. In addition, when the CPU carries out the read-access process on the memory 2, the data read out from the memory 2 as the data to be checked and corrected is read out through the above-mentioned ECC circuit 3 and stored in a first data buffer 5 as BUF 1. When the ECC circuit 3 checks that data has 1 bit being in error, the data in which an error is corrected is stored in the first data buffer 5. The CPU then reads out data stored in the first data buffer 5 once.

The data read out from the memory 2 at the time of the read-access process is simultaneously directly stored in a second data buffer 6 as BUF 2 without passing through the ECC circuit 3. Each of the data respectively stored in the first data buffer 5 and the second data buffer 6 is inputted to a comparator 7 as a magnitude comparator. The comparator 7 compares two pieces of input data and outputs a high-level signal to one of the input terminals of an EXOR gate 8 as one part of the error check and correction (ECC) monitoring circuit when 1 bit is in error. In addition, when having a 2-bit error, the comparator 7 outputs the high-level signal (ERROR) to one of the three input terminals of an OR gate 9 as one part of the ECC monitoring circuit.

When the ECC circuit 3 carries out correction for 1 bit being in error, the error/correction output device 4 outputs the high-level signal to another input terminal of the EXOR gate 8. When the ECC circuit 3 carries out the checking of 2 or more bits being in error, the error/correction output device 4 outputs the high-level signal to another one of the input terminals of the OR gate 9. Subsequently, the other one of the input terminals of the OR gate 9 is connected to the output terminal of the EXOR gate 8.

The output terminal of the OR gate 9 is connected to one of the input terminals of an AND gate 10. A signal, which controls an output of a signal from the AND gate 10, is provided to the other terminal of the AND gate 1—when the CPU carries out a write-in process to a register (not shown). The control signal is set at the high-level (H) when the microcomputer including the memory diagnosis circuit 1 and the memory 2 carries out a normal operation. The situation (at the time of functional check) where the control signal is set at a low-level (L) is described in a second embodiment. When the output signal of the AND gate 10 is at the high-level, since an abnormal check signal indicative of having an abnormality in the ECC circuit 3 is generated, the control signal is set to be a signal (RESET) for resetting, for example, the microcomputer and notifies of an abnormality detection to a generic control device.

The following illustrates the operation in the present embodiment. When the CPU carries out the read-access process to the memory 2, the read-out data is stored in the first data buffer 5 through an error correction process carried out by the ECC circuit 3 and is stored in the second data buffer as mentioned above. The comparator 7 then compares the data stored in each of the data buffers 5 and 6. If the data read out from the memory 2 does not have an error, each of signals outputted from the comparator 7 and the error/correction output device 4 is indicated as the low-level signal. Therefore, the output signal of the AND gate 10 is also at the low-level. It is noted that the following terms “Normal” and “Abnormal” are used for evaluating the operation of the ECC circuit 3.

(A) <at Normal Timing: Correcting 1-Bit being in Error>

The ECC circuit 3 detects 1-bit being in error in the data read out from the memory 2 and corrects the error, and then the corrected data is stored in the first data buffer 5. As a result, 1-bit difference occurs between the data stored in the first data buffer 5 and the data stored in the second data buffer 6, the comparator outputs a high-level signal to the EXOR gate 8. Since the ECC circuit 3 carries out the correction process, the error/correction output device 4 also outputs a high-level signal to the EXOR gate 8. Accordingly, the output signal of the EXOR gate 8 is at the low-level.

When a period for masking the output signal of the EXOR gate at a normal operation timing is required in response to a timing of the read-access process carried out by the CPU, a logic gate may be properly provided between the EXOR gate 8 and the OR gate 9.

(B) <at Abnormal Timing: Having 1-Bit Difference without Correction>

On the other hands, although 1-bit difference occurs between the data stored in the data buffer 5 and the data stored in the data buffer 6 and the comparator 7 outputs a high-level signal to the EXOR gate 8, when the ECC circuit does not carry out the correction process, the error/correction output device 4 outputs the low-level signal. Accordingly, a fault is detected when the output signal of the EXOR gate 8 is at the high-level and the output signal of the AND gate 10 through the OR gate 9 is at the high-level.

In this situation, if there is a high possibility that the value of data stored in the second data buffer 6 is different from the value of data read out by the ECC circuit 3 from the memory 2, there is a high possibility that the ECC circuit 3 has a fault. Therefore, it can be avoided that the CPU uses the data, which is not guaranteed to be accurate, in the first data buffer 5 to be read out.

(C) <at Abnormal Timing: Having No 1-Bit Difference and Having Correction>

As opposite to the situation in (B), when the comparator 7 outputs the low-level signal to the EXOR gate 8; however, the ECC circuit 3 carries out the correction process, since the EXOR gate 8 outputs the high-level signal, the AND gate 10 outputs the high-level signal and then a fault is detected. In this situation, 1-bit difference occurs between the data stored in the first data buffer 5 and the data stored in the second data buffer 6; however, the ECC circuit 3 carries out the correction process and both data are assumed to be identical as a result.

In addition, since the ECC circuit 3 also carries out the correction process when there is no error in the data read out by the CPU; and 1-bit error occurs in ECC bits corresponding to the data, the situation is also the same as (C). However, in this situation, the data stored in the first data buffer 5 has to be validated. When a 1-bit error occurs, it is possible to determine whether a 1-bit error occurs in the data read out by the CPU or the KC bits by referring to the ECC bits.

For example, when status bits having 3 bits are generated from the ECC bits, these bits are defined in the following, and are inputted to the error/correction output device 4.

1^{st} bit: the data having 2 or more bits being in error->outputting “Error”;

2^{nd} bit: the data having 1 bit being in error->outputting “Correction”; and

3^{rd} bit: the ECC bits having 1 bit being in error->without outputting “Correction”.

The error/correction output device 4 decides whether to output “Error” or “Correction” by referring to the above-mentioned status bits. In the situation (C), the r bit is established so that the signal outputting to the EXOR gate 8 is still at the low-level.

(D) <at Normal Timing: Checking 2 or More Bits being in Error>

When the ECC circuit 3 checks that there are 2 bits being in error in the data read out by the memory 2, the error/correction output device 4 outputs the high-level signal (ERROR) to the OR gate 9. Accordingly, when the output signal of the AND gate 10 is at the high-level, the fault is detected. Also in this situation, it is avoided that the CPU reads out the data stored in the first data buffer 5 and uses the data.

(E) <at Abnormal Timing: Having 2 or More Bits Difference Between Both Data>

When there are 2-bits difference between the data stored in the first data buffer 5 and the data stored in the second data buffer 6, the comparator 7 outputs the high-level signal to the OR gate 9. Accordingly, when the output signal of the AND gate 10 is at the high-level, the fault is detected. This situation is identical to (B) in that a fault occurs in the ECC circuit 3 when there is a difference between the value of the data stored in the second data buffer 6 and the value of data read out by the ECC circuit 3 from the memory 2.

According to the present embodiment as mentioned above, in the memory diagnosis circuit 1, the ECC circuit 3 carries out the error check of 2 or more bits being in error and the error correction of 1 bit being in error on the data written into and read out from the memory 2. The data read out from the memory 2 and corrected by the ECC circuit 3 is stored in the first data buffer 5, and the data read out from the memory is directly stored in the second data buffer 6, The comparator 7 then compares the data values stored in the first data buffer 5 and the second data buffer 6 respectively.

The ECC monitoring circuit configured by the EXOR gate 8 and the OR gate 9 validates the data value stored in the first data buffer 5 in a case where there is 1 bit difference between both data values based on the comparison result of the comparator 7 and the ECC circuit 3 corrects the error, and invalidates the data value stored in the first data buffer 5 in the above mentioned cases (B), (C), and (E) at the abnormal timing and the case (D) at the normal timing. Accordingly, it is easier to determine whether the abnormality occurs in the ECC circuit 3.

In addition, the error/correction output device 4 masks the “Correction” signal without outputting the signal to the EXOR gate 8, when there is no error in the data stored in the first data buffer 5; and there is 1-bit error in the ECC bits corresponding to the data and the correction of the data occurs. Accordingly, it can be avoided that the data having no error stored in the first data buffer 5 is invalidated. In addition, the external logic configuration for this purpose can be made simpler.

Herein, the error/correction output device 4 stores the status bits into the registers and holds the status bits, and it is possible to determine whether the “Error” or “Correction” occurs when the status bits held by the generic control device or the like is read out after the diagnosis. In addition, it is also possible to determine whether the “Error” or “correction” occurs in how many bits being in error.

Accordingly, when, for example, the value of “N” is relatively larger, an external control device or the like can recognize a state where the ECC circuit 3 is normally in an operation as a result of the ECC circuit 3 carrying out the error correction before the “Error” occurs. Therefore, the approach such as the exchange of the memory 2 can be done in advance when an error as an alarm occurs at the normal operation step before reaching the “Fault” state.

Moreover, when comparing number of bits being in error based on the status bits, failure analysis can also be carried out easily. In addition, the error output device 4 can also carry out the failure analysis in detail by holding the positions of bits corrected by the ECC circuit 3.

### Second Embodiment

The following omits the description of the identical parts appended by the identical reference numerals in the first embodiment, and only describes the parts different from the first embodiment. As shown in FIG. 2, the check data storage region 12 is arranged in the memory 11, which is in replacement of the memory 2, in the second embodiment. The first check data and the second check data are stored into the check data storage region 12 in advance. The first check data and the second check data are used to carry out the check sequence for confirming whether the function of the ECC circuit 3 is in a normal situation when the system including the memory diagnosis circuit 1 is activated.

The first check data is set as a combination indicative of the read out data and ECC bits having 1 bit being in error, and the second check data is set as a combination of the read out data and the ECC bits having 2 or more bits being in error. In this situation, the CPU sets one of the input terminals of the AND gate as one part of the ECC monitoring circuit to be at the low-level, and inhibits a reset signal to be outputted.

As shown in FIG. 2, when the CPU reads out the second check data, if the data stored in the first data buffer 5 and the data stored in the second data buffer 6 are identical; however, the ECC circuit 3 is in a normal operation, the error/correction output device 4 outputs “Error.” Accordingly, the output signal of the OR gate 9 is at the high-level.

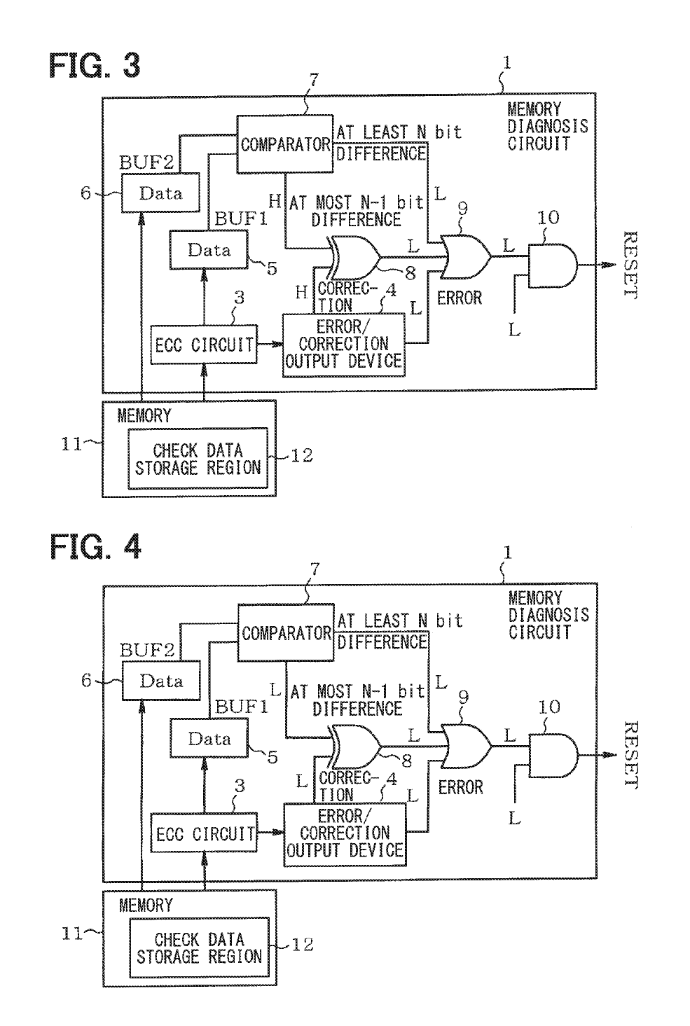

As shown in FIG. 3, when the CPU reads out the first check data, since the ECC circuit 3 in a normal operation detects 1 bit being in error and correct the error, the error correction output device 4 outputs “Correction.” In addition, the comparator 7 checks that there is 1 bit difference. Accordingly, the output signal of the OR gate 9 is at the low-level.

As shown in FIG. 4, when the CPU reads out the first check data set to be having 1 bit being in error in the ECC bits, since the ECC circuit 3 in an normal operation corrects the 1 bit being in error, the data stored in the first data buffer 5 and the second data buffer 6 are identical. In this situation, as described in the first embodiment, the error correction output device 4 masks the “Correction” without outputting the “Correction.” Accordingly, as similar to the situation illustrated in FIG. 3, the output signal of the OR gate 9 is at the low-level.

Accordingly, when the output state of each signal in each situation is confirmed, it can be confirmed whether the ECC circuit 3 functions normally or not.

According to the second embodiment as mentioned above, the memory 11 includes the check data storage region 12 storing the first check data and the second check data in advance. At the time of activation, when the CPU reads out the first check data and the second check data from the check data storage region 12, the ECC circuit 3 carries out the check sequence for confirming whether the ECC circuit 3 is normally in operation; and invalidates the function of the memory diagnosis circuit 1 by providing the low-level signal to one of the input terminals of the AND gate 10. Accordingly, it can be confirmed whether the function of the ECC circuit 3 is normal without outputting a reset signal to outside.

The present disclosure is not only limited to the embodiments illustrated in the drawings, but also can be modified or enlarged as shown in the following. When there is no any problem as ignoring a situation in which 1 bit being in error in the ECC bits, the situation can be regarded as the abnormal timing in (C). In addition, the function of the error correction output device 4 can be implemented into the ECC circuit 3. In addition, N may set as “3” or more. Furthermore, the output signal of the AND gate 10 is not necessarily to be set as the reset signal; for example, when an interruption happens in CPU, and then the subsequence processes may be relied on the CPU. (For instance, when the interruption occurs several times, then the reset is outputted.)

While the present disclosure has been described with reference to embodiments thereof, it is to be understood that the disclosure is not limited to the embodiments and constructions. The present disclosure is intended to cover various modification and equivalent arrangements. In addition, the various combinations and configurations, other combinations and configurations, including more, less or only a single element, are also within the spirit and scope of the present disclosure.

1. A memory diagnosis circuit comprising:
an error check and correction circuit that carries out
an error check of data, which is written into a memory and read out from the memory, having N or more bits being in error, and
an error correction of data, which is written into the memory and read out from the memory, having (N−1) or less bits being in error;
a first data buffer that stores the data, which is read out from the memory and corrected by the error check and correction circuit;
a second data buffer that directly stores the data read out by the memory;
a comparator that compares a value of the data stored in the first data buffer and a value of the data stored in the second data buffer; and
an error check and correction monitoring circuit, wherein:
the error check and correction monitoring circuit validates the value of the data stored in the first data buffer, when
a comparison result of the comparator indicates (N−1) or less bits being different between the value of the data stored in the first data buffer and the value of the data stored in the second data buffer, and
the error check and correction monitoring circuit confirms that the error check and correction circuit carries out the error correction;
the error check and correction monitoring circuit invalidates the value of the data stored in the first data buffer and outputs an abnormal signal, when
i) the comparison result of the comparator indicates (N−1) or less bits being different between the value of the data stored in the first data buffer and the value of the data stored in the second data buffer, and the error check and correction monitoring circuit confirms that the error check and correction circuit does not carry out the error correction, or
ii) the error check and correction monitoring circuit confirms that the error check and correction circuit carries out the error correction, although (N−1) or less bits not being in different between the value of the data stored in the first data buffer and the value of the data stored in the second data buffer, or
iii) the comparison result of the comparator indicates N or more bits being in different between the value of the data stored in the first data buffer and the value of the data stored in the second data buffer, or
iv) the error check and correction monitoring circuit confirms that the error check and correction circuit carries out the error check; and
the N is a natural number to be equal to 2 or more.

2. The memory diagnosis circuit according to claim 1,
wherein the error check and correction circuit masks an execution of an error correction of error check data, which is used for carrying out an error check and an error correction, corresponding to the data without having 1 or more bits being in error stored in the first data buffer, on the error check and correction monitoring circuit, when there are (N−1) or less bits being in error in the error check data and the error check and correction circuit carries out the error correction.

3. The memory diagnosis circuit according to claim 1, further comprising:
a check data storage region that preliminarily stores
first check data set to be having (N−1) or less bits being in error in a combination of data to be checked or corrected and error check data for an error check and an error correction, and
second check data set to be having N or more bits being in error in the combination,
wherein the error check and correction monitoring circuit invalidates a function of the error check and correction monitoring circuit, when a CPU reads out the first check data and the second check data from the check data storage region and carries out a check sequence for confirming whether the error check and correction circuit is in a normal operation at a time of activation.
